(19) United States
(12) Patent Application Publication
(10) Pub. No.: US 2016/0247941 A1
(43) Pub. Date: Aug. 25, 2016

(54) THIN FILM TRANSISTOR, ARRAY SUBSTRATE AND DISPLAY DEVICE

(71) Applicant: BOE TECHOLOGY GROUP CO., LTD., Beijing (CN)

(72) Inventors: Yoon Sung UM, Beijing (CN); Xiaolin WANG, Beijing (CN); Xing YAO, Beijing (CN); Haiyan WANG, Beijing (CN)

(21) Appl. No.: 14/437,155

(22) PCT Filed: Oct. 16, 2014
(86) PCT No.: PCT/CN2014/088768

§ 371 Date: Apr. 20, 2015

(30) Foreign Application Priority Data
May 26, 2014 (CN) 201410225263.2

(51) Int. Cl. H01L 29/786

(52) U.S. Cl. CPC H01L 29/78696; H01L 29/7869; H01L 27/1251

(57) ABSTRACT

Disclosed is a thin film transistor, an array substrate and a display device. The thin film transistor includes: a gate, an active layer, a source and a drain disposed on a base substrate. The source and the drain are disposed oppositely and electrically connected with the active layer respectively, and the orthographic projection of the active layer region (a) corresponding to the gap between the source and the drain on the base substrate is in a bend shape. For the thin film transistor, the sharp increase of switch-off current can be avoided by increasing the length of the active layer region corresponding to the gap between the source and the drain without increasing the area occupied by TFT.

### TECHNICAL FIELD

Embodiments of the present invention relate to a thin film transistor, an array substrate, and a display device.

### BACKGROUND

Currently, it is well known as display devices, such as liquid crystal display (LCD) panel, electroluminescence (EL) display panel, and electronic paper display panel, etc. There is a thin film transistor (TFT) which controls each pixel switch in these display devices. The TFT is categorized into top-gate TFT and bottom-gate TFT according to the different position of a gate.

### SUMMARY

Embodiments of the present invention relates to a thin film transistor, an array substrate and a display device.

In first respect of the present invention, there is provided a thin film transistor, which comprises: a gate, an active layer, a source and a drain disposed on a base substrate, the source and the drain are disposed oppositely and electrically connected with the active layer respectively, the orthographic projection of the active layer region corresponding to the gap between the source and the drain on the base substrate is in a bend shape.

As an example, the orthographic projection of the active layer corresponding to the gap between the source and the drain on the base substrate is in a fold line shape or a curve shape.

As an example, an insulation layer is disposed between a film layer where the source and drain are located and the active layer, the source and the drain are respectively electrically connected with the active layer through a via hole in the insulation layer; or the source and the drain are directly disposed on the active layer, the source and the drain are directly electrically connected with the active layer.

As an example, the material of the active layer is semiconductor oxide.

As an example, the thin film transistor is a top-gate TFT or a bottom-gate TFT.

In second respect of the present invention, there is provided an array substrate, which comprises the aforementioned thin film transistor.

As an example, the array substrate further comprises: a gate line electrically connected with the gate of thin film transistor, a data line electrically connected with the source of thin film transistor, and a pixel electrode electrically connected with the drain of thin film transistor.

As an example, the source and the drain of thin film transistor are arranged along the extending direction of the gate line.

As an example, the gap between the drain of thin film transistor and the most adjacent data line is more than 5.0 μm.

As an example, a passivation layer is disposed between the drain of thin film transistor and the pixel electrode, the drain is electrically connected with the pixel electrode through a via hole in the passivation layer; or the pixel electrode is directly disposed on the drain of thin film transistor, the drain is directly electrically connected with the pixel electrode.

In third respect of the present invention, there is provided a display device, which comprises the aforementioned array substrate.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 schematically illustrates a known thin film transistor;

FIGS. 2a and 2b are top views of known array substrates;

FIG. 3 schematically illustrates a thin film transistor according to an embodiment of the present invention;

FIGS. 4a, 4b, and 4c schematically illustrate three thin film transistors respectively according to embodiments of the present invention;

FIGS. 5a, 5b, and 5c schematically illustrate the other three thin film transistors respectively according to embodiments of the present invention;

FIGS. 6a, 6b, and 6c schematically illustrate respective array substrates according to embodiments of the present invention.

### DETAILED DESCRIPTION

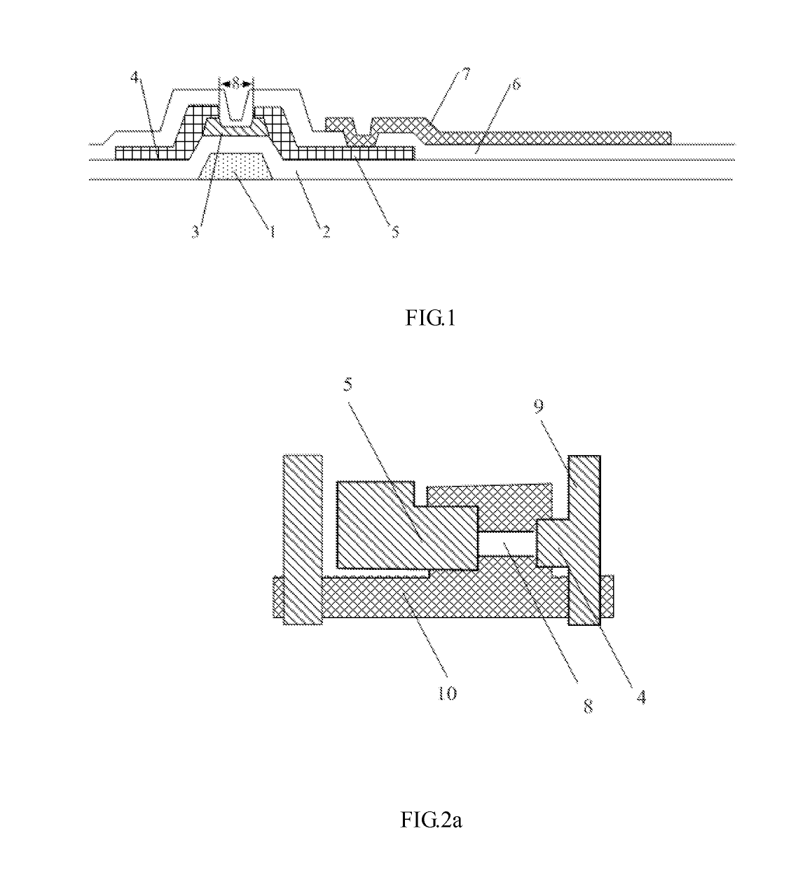

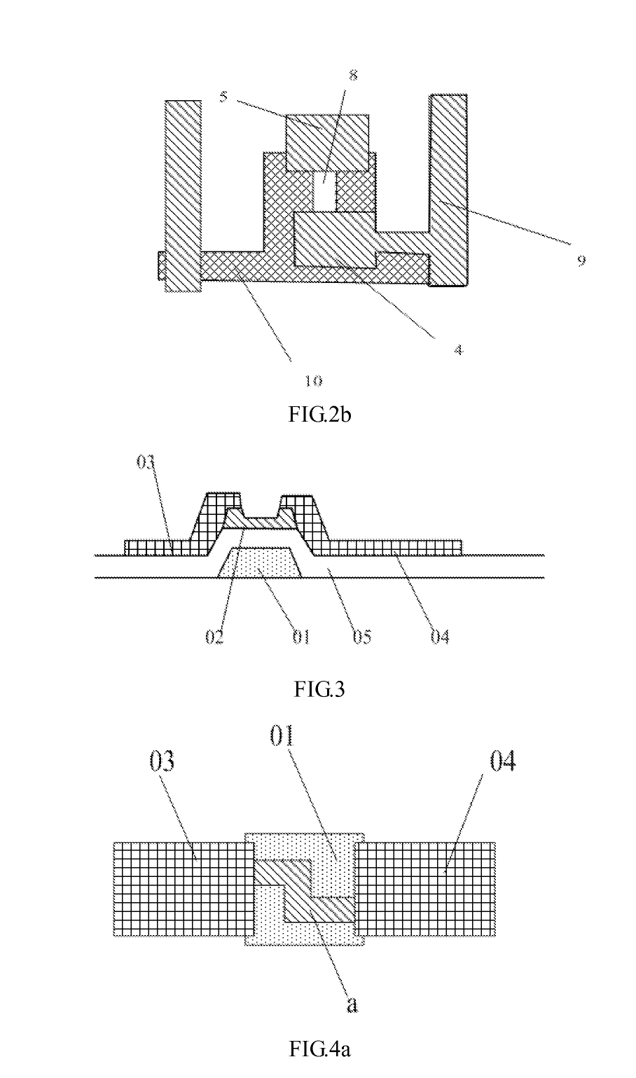

FIG. 1 schematically illustrates a known bottom-gate TFT, the TFT comprises a gate 1, an active layer 3, a source 4 and a drain 5, which disposed successively on a base substrate. A passivation layer 6 is disposed on the source 4 and the drain 5, the drain 5 is electrically connected with the pixel electrode 7 through a via hole in the passivation layer 6. A known array substrate is illustrated in FIGS. 2a and 2b, generally, a gate 1 is electrically connected with a gate line 10, a source 4 is electrically connected with a data line 9. While a gate scanning signal is loaded on the gate 1, the active layer 3 on the gate 1 is changed from semiconductor to conductor, and a current channel is formed between the source 4 and the drain 5 in the area of the active layer 3 facing the gate 1. The current channel transmits data signals loaded on the source 4 from the data line 9 to the pixel electrode 7 through the drain 5, thus the pixel electrode 7 is in working state.

When the known TFT is used in an array substrate, there are two ways to design an active layer region 8a between the source 4 and the drain 5: one of the design ways is illustrated in FIG. 2a, where the extending direction of the active layer region 8 between the source 4 and the drain 5 is parallel with the gate line 10. In this way, a high space utilization ratio is achieved, but when the TFT is used in high resolution displays, the length of the active layer region 8 between the source 4 and the drain 5 is limited, because the area of each pixel is small, and the distance between the drain 5 and the data line 9 needs to be more than 5.0 μm in order to avoid short circuit; the length of the active layer region 8 between the source 4 and the drain 5 is both related to switch-on current (Ion) and switch-off current (Ioff) of the TFT. If the length of the active layer region 8 between the source 4 and the drain 5 is too small, the switch-off current will increase abruptly. The other design way is illustrated in FIG. 2b, where the extending direction of the active layer region 8 between the source 4 and the drain 5 is vertical to the gate line 10, in this way, the short circuit between the drain 5 and the data line 9 is avoided, but the space utilization ratio is lower, it is not ensured that each pixel has a high aperture ratio in high resolution displays.

Embodiments of the present invention provide a thin film transistor, an array substrate, and a display device, by increasing the length of the active layer region between the source and the drain, the switch-off current could not increases abruptly while a high space utilization ratio is ensured.

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at lease one. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

Thickness of each film layer, the size or the shape of each area in drawings does not represent the real scale of the TFT component, it is merely to illustrate the present invention in an explanatory manner.

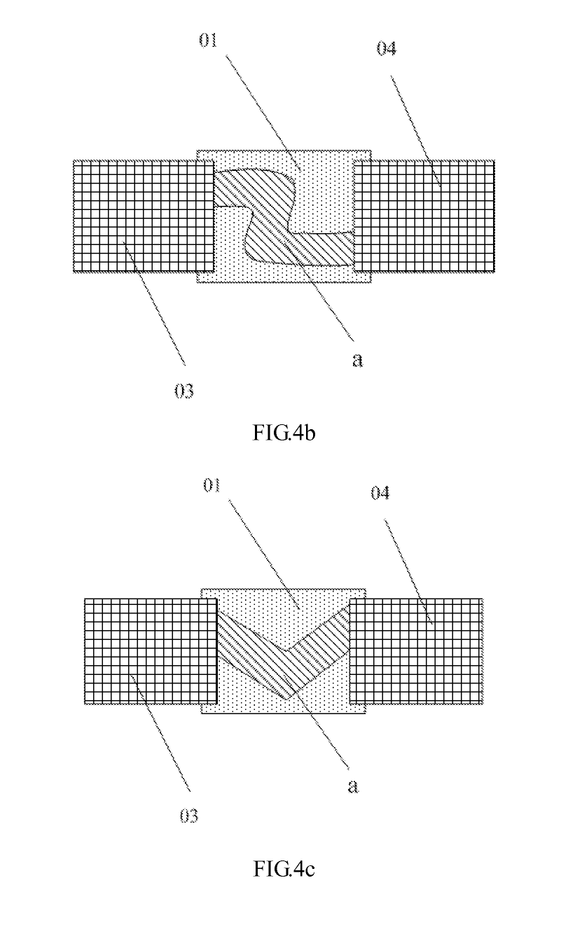

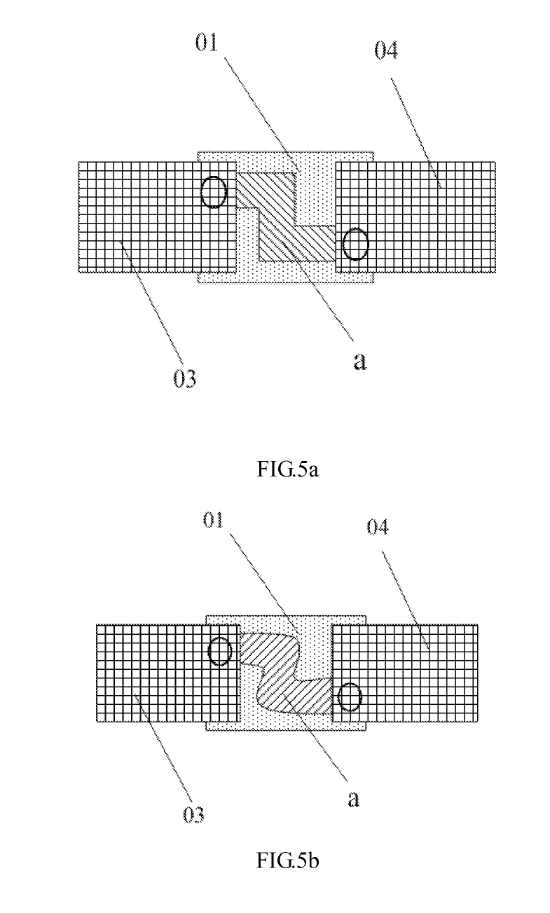

An embodiment of the present invention provides a TFT, as illustrated in FIG. 3, the TFT comprises: a gate 01, an active layer 02, a source 03 and a drain 04, which are disposed on a base substrate; the source 03 and the drain 04 are disposed oppositely and electrically connected with the active layer 02 respectively; as illustrated in FIGS. 4a to 4c, the orthographic projection of the active layer region α corresponding to the gap between the source 03 and the drain 04 projected onto the base substrate has a bend shape, that is to say, the shape of the orthographic projection projected onto the base substrate is not a straight line.

In above TFT provided in the embodiment of the invention, the active layer region α corresponding to the gap between the source 03 and the drain 04 is designed in a bend shape, compared with a known active layer in a straight line shape, the length of the active layer region α corresponding to the gap between the source 03 and the drain 04 is increased without increasing the area occupied by the TFT, thus, the sharp increase of switch-off current is avoided.

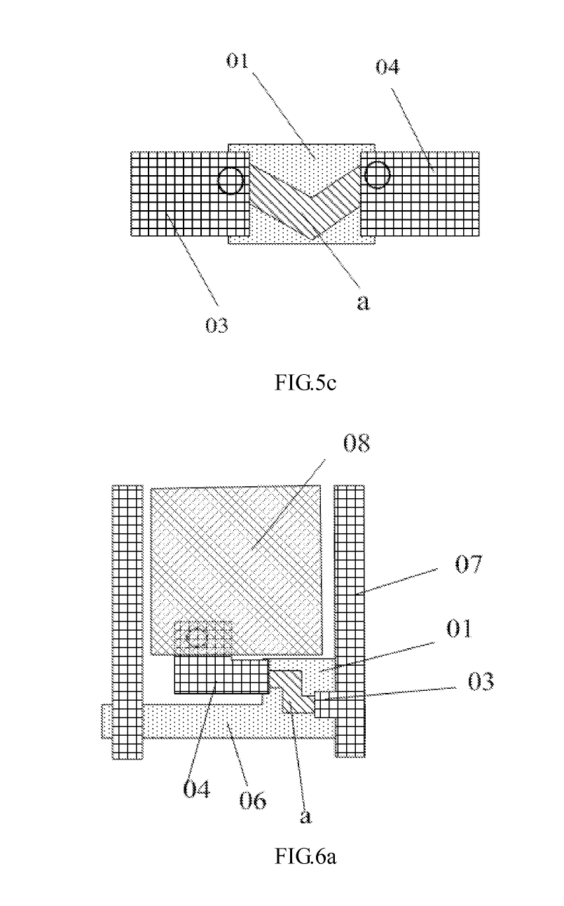

As an example, the shape of the orthographic projection of the active layer region α corresponding to the gap between the source 03 and the drain 04 on the base substrate may be a fold line, or a curve, etc., which is not limited here. For example, the active layer region α corresponding to the gap between the source 03 and the drain 04 is designed in a zigzag fold line shape, as illustrated in FIGS. 4a and 5a; the active layer region α corresponding to the gap between the source 03 and the drain 04 may also be designed in a zigzag arc shape, as illustrated in FIGS. 4b and 5b; the active layer region α corresponding to the gap between the source 03 and the drain 04 may also be designed in a fold line shape with an angle, as illustrated in FIGS. 4c and 5c. The shapes of above patterns are merely for illustrative purpose and not limitative herein. In practice, the shape of specific pattern is designed according to the design precision in a patterning process, which is not limited herein. Because the active layer region α corresponding to the gap between the source 03 and the drain 04 is designed in a bend shape, the length of the active layer region α corresponding to the gap between the source 03 and the drain 04 is effectively increased, thus, the sharp increase of TFT switch-off current is avoided.

As an example, an insulation layer is disposed between the source 03/drain 04 and the active layer 02. For example, the source 03 and the drain 04 are electrically connected with the active layer 02 through a via hole formed in the insulation layer, as illustrated in FIGS. 5a to 5c. Alternatively, the source 03 and the drain 04 are directly disposed on the active layer 02, then the source 03 and the drain 04 are directly electrically connected with the active layer 02, as illustrated in FIGS. 4a to 4c. Thus, no matter which connection modes between the source 03, the drain 04 and the active layer 02 are used in the TFT design, the active layer region α corresponding to the gap between the source 03 and the drain 04 could be designed in a bend shape, compared with a known active layer in a straight line shape, the length of the active layer region α corresponding to the gap between the source 03 and the drain 04 is increased without increasing the area occupied by the TFT, thus, the sharp increase of switch-off current is avoided.

The active layer 02 may be made from semiconductor oxide material or amorphous silicon material, which is not limited herein. If the active layer 02 of TFT is made from semiconductor oxide material, it is more convenient to form a bend shape by a patterning process, then the sharp increase of switch-off current can be avoided by increasing the length of the active layer region corresponding to the gap between the source 03 and the drain 04.

The above TFT according to the embodiments of the present invention may be a top-gate TFT or a bottom-gate TFT, which is not limited herein. In all the embodiments of the present invention, a bottom-gate TFT is taken as an example. For example, in the bottom-gate TFT illustrated in FIG. 3, a gate insulation layer 05 is generally disposed between the gate 01 and the active layer 02. When the TFT provided in embodiments of the present invention is used in a top-gate or a bottom-gate configuration, the active layer region α corresponding to the gap between the source 03 and the drain 04 could be designed in a bend shape, compared with a known active layer in a straight line shape, the length of the active layer region α corresponding to the gap between the source 03 and the drain 04 is increased without increasing the area occupied by the TFT, thus, the sharp increase of switch-off current is avoided.

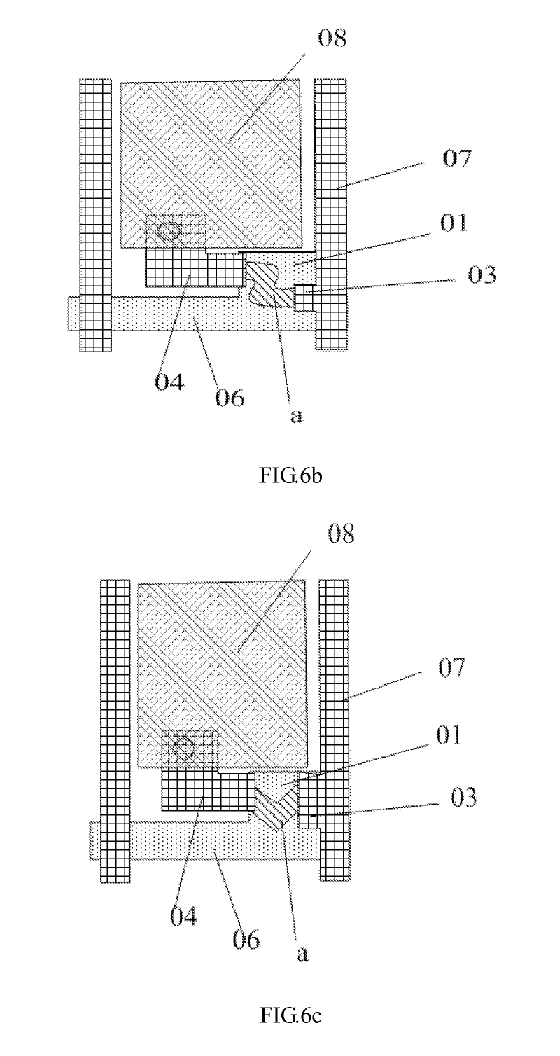

An embodiment of the present invention further provides an array substrate, as illustrated in FIGS. 6a to 6c, which comprises the above TFT provided in the embodiments of the present invention.

As an example, the array substrate further comprises: a gate line 06 electrically connected with a gate 01 of thin film transistor, a data line 07 electrically connected with a source 03 of TFT, and a pixel electrode 08 electrically connected with a drain 04 of TFT.

In the above array substrate provided in the embodiment of the present invention, the active layer region α corresponding to the gap between the source 03 and the drain 04 of TFT is designed in a bend shape. Compared with the known active layer region in a straight line shape, in case of the same area occupied by TFT, the length of the active layer region corresponding to the gap between the source and the drain is increased. Thus, a high aperture ratio can be achieved by minimizing the area occupied by TFT while ensuring the switch-off current, especially used in high resolution displays.

As an example, as illustrated in FIGS. 6a to 6c, the source 03 and the drain 04 of TFT are arranged along the extending direction of the gate line 06, this arrangement is better for increasing the space utilization ratio of each pixel of an array substrate, especially used in high resolution displays, thus, a high aperture ratio can be achieved.

As an example, the gap between the drain 04 of TFT and the most adjacent data line 07 is designed to be more than 5.0 μm, in order to avoid short circuit between the drain 04 and the most adjacent data line 07, while the source 03 and the drain 04 of TFT are arranged along the extending direction of the gate line 06.

As an example, there are two connection ways between the drain 04 and the pixel electrode 08 of TFT: first, a passivation layer is disposed between the drain 04 and the pixel electrode 08, the drain 04 is electrically connected with the pixel electrode 08 through a via hole in the passivation layer; second, the pixel electrode 08 is directly disposed on the drain 04 of TFT, the drain 04 is directly electrically connected with the pixel electrode 08, as illustrated in FIGS. 6a to 6c.

For the TFT adopting any one of the two connection ways, the active layer region α corresponding to the gap between the source 03 and the drain 04 could be designed in a bend shape, compared with a known active layer in a straight line shape, the length of the active layer region α corresponding to the gap between the source 03 and the drain 04 is increased without increasing the area occupied by the TFT, thus, the sharp increase of switch-off current is avoided.

As an example, the above array substrate provided in the embodiment of the present invention may be used in LCD panels, and may also be used in OLED panels, which is not limited herein.

An embodiment of the present invention further provides a display device, which comprises the aforementioned array substrate provided in embodiments of the present invention. The display device may be a display, mobile phone, TV, notebook and All-in-one computer, etc. It is understood for those skilled in the art that other essential components of the display device are also included in the display device, which is not elaborated herein and should not be limitative to the disclosure.

For the above TFT, array substrate and display device provided in embodiments of the present invention, the active layer region corresponding to the gap between the source and the drain of TFT is designed in a bend shape, compared with a known active layer region in a straight line shape, the sharp increase of switch-off current is avoided by increasing the length of the active layer region corresponding to the gap between the source and the drain without increasing the area occupied by TFT. Additionally, the length of the active layer region corresponding to the gap between the source and the drain is increased with the same area occupied by TFT, thus, a high aperture ratio can be achieved by minimizing the area occupied by TFT while ensuring the switch-off current, especially used in high resolution displays.

What is described above is related to the illustrative embodiments of the disclosure only and not limitative to the scope of the disclosure; the scopes of the disclosure are defined by the accompanying claims.

The present application claims priority from Chinese Application Serial Number 201410225263.2 filed on May 26, 2014, the disclosure of which is hereby incorporated by reference herein in its entirety.

1. A thin film transistor, comprising: a gate, an active layer, a source and a drain disposed on a base substrate, the source and the drain being disposed oppositely and electrically connected with the active layer respectively,
wherein an orthographic projection of the active layer region corresponding to the gap between the source and the drain on the base substrate is in a bend shape.

2. The thin film transistor according to claim 1, wherein the orthographic projection of the active layer region corresponding to the gap between the source and the drain on the base substrate is in a fold line shape or a curve shape.

3. The thin film transistor according to claim 1, wherein an insulation layer is disposed between a film layer where the source and drain are located and the active layer, the source and the drain are respectively electrically connected with the active layer through a via hole in the insulation layer.

4. The thin film transistor according to claim 1, wherein the film layer where the source and drain are located is directly disposed on the active layer, the source and the drain are directly electrically connected with the active layer.

5. The thin film transistor according to claim 1, wherein a material of the active layer is semiconductor oxide.

6. The thin film transistor according to claim 5, wherein the thin film transistor is a top-gate TFT or a bottom-gate TFT.

7. An array substrate, comprising: a thin film transistor according to claim 1.

8. The array substrate according to claim 7, further comprising: a gate line electrically connected with the gate of thin film transistor, a data line electrically connected with the source of thin film transistor, and a pixel electrode electrically connected with the drain of thin film transistor.

9. The array substrate according to claim 8, wherein the source and the drain of thin film transistor are arranged along an extending direction of the gate line.

10. The array substrate according to claim 9, wherein a gap between the drain of thin film transistor and the most adjacent data line is more than 5.0 μm.

11. The array substrate according to claim 8, wherein a passivation layer is disposed between the drain and the pixel electrode of thin film transistor, the drain is electrically connected with the pixel electrode through a via hole in the passivation layer.

12. The array substrate according to claim 8, wherein the pixel electrode is directly disposed on the drain of thin film transistor, the drain is directly electrically connected with the pixel electrode.

13. A display device, comprising: an array substrate according to claim 7.

14. The array substrate according to claim 7, wherein the orthographic projection of the active layer region corresponding to the gap between the source and the drain on the base substrate is in a fold line shape or a curve shape.

15. The array substrate according to claim 7, wherein an insulation layer is disposed between a film layer where the source and drain are located and the active layer, the source and the drain are respectively electrically connected with the active layer through a via hole in the insulation layer.

16. The array substrate according to claim 7, wherein the film layer where the source and drain are located is directly disposed on the active layer, the source and the drain are directly electrically connected with the active layer.

17. The array substrate according to claim 7, wherein a material of the active layer is semiconductor oxide.

18. The array substrate according to claim 7, wherein the thin film transistor is a top-gate TFT or a bottom-gate TFT.
